(19) United States
(12) Patent Application Publication
(10) Pub. No.: US 2005/0244618 A1
(43) Pub. Date: Nov. 3, 2005

(54) Islanded pattern for printing on readdressable media

(76) Inventors: Brian Gobrogge, Ann Anbun, MI (US); Gordon Andrews, Plymouth, MI (US)

Correspondence Address: Steven J. Moore;Pillsbury Winthrop, LLP, 695 East Main Street, P.O. Box 6760, Stamford, CT, 06904-6780, US

(21) Appl. No.: 10/836,092

(22) Filed: Apr. 30, 2004

(51) Int. Cl. H01L 29/76

(52) U.S. Cl. 428/195.1

(57) ABSTRACT

An islanded pattern for printing to a writeable media is disclosed. The islanded pattern includes a plurality of conductive islands arranged in columns. Islands in a first column are offset by a substantially uniform, non-zero stagger distance from islands in a second column that is an odd number of columns away from the first column. Islands in a first column possess a substantially identical arrangement to islands in a second column that is an even number of columns away from the first column. A distance substantially equal to the stagger distance may separate islands within a column. Each island may possess a height and width substantially equal to the stagger distance. Writeable media and display devices incorporating the islanded pattern are disclosed.

### TECHNICAL FIELD

This invention relates generally to the field of visual displays. More particularly, this invention relates to readdressable media, such as electric paper, that incorporates islanded surfaces arranged in a specified pattern designed to help improve an image in the readdressable media.

### BACKGROUND

Various types of writable media, commonly known as electric paper, exist in the prior art. One example of electric paper includes a polymer substrate and bichromal anisotropic particles, such as balls or cylinders that are in suspension with an enabling fluid and are one color, such as white, on one side and a different color, such as black, on the other. Examples of such electric paper are described in U.S. Pat. No. 5,723,204 to Stefik and U.S. Pat. No. 5,604,027 to Sheridon, each of which is incorporated herein by reference in its entirety. Under the influence of an electric field, the particles rotate so that either the white side or the black side is exposed.

Another type of electric writable media is known as an electronic ink display, such as the one described in U.S. Pat. No. 6,518,949 to Drzaic, which is incorporated herein by reference. An electronic ink display includes at least one capsule filled with a plurality of particles, made of a material such as titania, and a dyed suspending fluid. When a direct current electric field of an appropriate polarity is applied across the capsule, the particles move to a viewed surface of the display and scatter light. When the applied electric field is reversed, the particles move to the rear surface of the display and the viewed surface of the display then appears dark.

Yet another type of electric writable media, also described in U.S. Pat. No. 6,518,949 to Drzaic, includes a first set of particles and a second set of particles in a capsule. The first set of particles and the second set of particles have contrasting optical properties, such as contrasting colors, and can have, for example, differing electrophoretic properties. The capsule also contains a substantially clear fluid. The capsule has electrodes disposed adjacent to it connected to a voltage source, which may provide an alternating-current field or a direct-current field to the capsule. Upon application of an electric field across the electrodes, the first set of particles moves toward a first electrode, while the second set of particles moves toward a second electrode. If the electric field is reversed, the first set of particles moves toward the second electrode and the second set of particles moves toward the first electrode. Other examples of writable media include liquid crystal, non-encapsulated electrophoretic displays and other displays.

It has been well proven that electrostatic writing can be done on erasable electric writeable media by swiping an array of electrodes across the surface with a printer-like motion, depositing charge on the surface in an image wise fashion. The charge, once deposited, places a voltage across the medium and causes it to change its electro-optic condition by rotating, twisting or otherwise moving elements. One method of implementing this technology has been to use an islanded structure of isolated conductive material on the top surface of the electric writeable media. Islands of conductive material act as conducting surfaces for charge deposition that do not tribocharge with the writing array of electrodes and distribute the charge across each pixel in a relatively uniform manner.

A conventional islanded structure is shown in FIG. 1. Each island, such as 105, is a square having a uniform side length. Each island is separated from its adjacent islands by a uniform distance in each of the horizontal and vertical directions.

One problem with islanded structures used with conventional electric writeable media is that a misalignment between a printer and the electric writeable medium can cause the electric writeable medium to display improper images. For example, if an intended image includes a straight line, an improperly aligned print head and medium can produce a jogged line instead. A jogged line occurs, for example, when a line shifts pixel rows on a cathode ray tube display. In an electric writeable media, a jogged line can occur when an edge of the line falls between the two rows or two columns of the islanded structure. In such a case, the print head of a printer may alternately charge islands in a left or right column (for a vertical line) or a top or bottom row (for a horizontal line). As such, the line may switch between the two rows or columns and appear jogged instead of straight. An improper jogged line can also be displayed if the print head does not move across the electric writeable medium in a direction that is substantially perpendicular to the columns of islands.

Therefore, a need exists for an electric writeable medium having an islanded surface structure that reduces the display of improperly printed images due to the misalignment between a printer and the media during the printing process.

The islanded surface structure described herein is directed to solving one or more of the above-listed problems.

### SUMMARY

Before the present methods and systems are described, it is to be understood that this invention is not limited to the particular methodologies and systems described, as these may vary. It is also to be understood that the terminology used in the description is for the purpose of describing the particular versions or embodiments only, and is not intended to limit the scope of the present invention which will be limited only by the appended claims.

It must also be noted that as used herein and in the appended claims, the singular forms “a,” “an,” and “the” include plural references unless the context clearly dictates otherwise. Thus, for example, reference to an “island” is a reference to one or more islands and equivalents thereof known to those skilled in the art, and so forth. Unless defined otherwise, all technical and scientific terms used herein have the same meanings as commonly understood by one of ordinary skill in the art. Although any methods, materials, and devices similar or equivalent to those described herein can be used in the practice or testing of embodiments of the present invention, the preferred methods, materials, and devices are now described. All publications mentioned herein are incorporated by reference. Nothing herein is to be construed as an admission that the invention is not entitled to antedate such disclosure by virtue of prior invention.

In an embodiment, a writeable medium includes a panel including a plurality of electrically changeable elements, a layer including an insulating material, and a plurality of islands located on one side of the layer. Each island includes a conductive material. The plurality of islands are arranged in a plurality of columns. Islands in a first column are offset by a substantially uniform, non-zero stagger distance with respect to islands in each second column that is separated from the first column by an odd number of columns. Islands in the first column possess substantially the same arrangement as islands in each third column that is separated from the first column by an even number of columns. In an embodiment, a distance between adjacent islands in a column is approximately equal to the stagger distance. In an embodiment, a distance between adjacent islands in a column is no more than approximately 4 mils. In an embodiment, the stagger distance is no more than approximately 4 mils. In an embodiment, a distance between adjacent columns is no more than approximately 4 mils. In an embodiment, an island is substantially a square. Each side of the island may be no more than approximately 4 mils. In an alternate embodiment, an island is substantially circular. The diameter of the island may be no more than approximately 4 mils. In alternate embodiments, an island may be substantially rectangular, trapezoidal, ovular or octagonal.

In an embodiment, a writeable medium includes a panel including a plurality of electrically changeable elements, and a layer including an insulating material and a plurality of islands. Each island includes a conductive material. The plurality of islands are arranged in a plurality of columns. Islands in a first column are offset by a substantially uniform, non-zero stagger distance with respect to islands in each second column that is separated from the first column by an odd number of columns. Islands in the first column possess substantially the same arrangement as islands in each third column that is separated from the first column by an even number of columns. In an embodiment, a distance between adjacent islands in a column is approximately equal to the stagger distance. In an embodiment, a distance between adjacent islands in a column is no more than approximately 4 mils. In an embodiment, the stagger distance is no more than approximately 4 mils. In an embodiment, a distance between adjacent columns is no more than approximately 4 mils. In an embodiment, an island is substantially a square. Each side of the island may be no more than approximately 4 mils. In an alternate embodiment, an island is substantially circular. The diameter of the island may be no more than approximately 4 mils. In alternate embodiments, an island may be substantially rectangular, trapezoidal, ovular or octagonal.

In an embodiment, a display device includes a print head and a writeable medium including a panel including a plurality of electrically changeable elements, a layer including an insulating material, and a plurality of islands located on one side of the layer. Each island includes a conductive material. The plurality of islands are arranged in a plurality of columns. Islands in a first column are offset by a substantially uniform, non-zero stagger distance with respect to islands in each second column that is separated from the first column by an odd number of columns. Islands in the first column possess substantially the same arrangement as islands in each third column that is separated from the first column by an even number of columns.

In an embodiment, a display device includes a print head and a writeable medium including a panel including a plurality of electrically changeable elements, and a layer including an insulating material and a plurality of islands. Each island includes a conductive material. The plurality of islands are arranged in a plurality of columns. Islands in a first column are offset by a substantially uniform, non-zero stagger distance with respect to islands in each second column that is separated from the first column by an odd number of columns. Islands in the first column possess substantially the same arrangement as islands in each third column that is separated from the first column by an even number of columns.

### BRIEF DESCRIPTION OF THE DRAWINGS

Aspects, features, benefits and advantages of the embodiments of the present invention will be apparent with regard to the following description, appended claims and accompanying drawings where:

FIG. 1 depicts an exemplary islanded surface structure pattern for reducing the effects of misalignment according to the prior art;

FIG. 2 depicts an exemplary islanded surface structure pattern for reducing the effects of misalignment according to an embodiment; and

FIG. 3 depicts an exemplary display device incorporating the islanded surface structure according to an embodiment.

### DETAILED DESCRIPTION

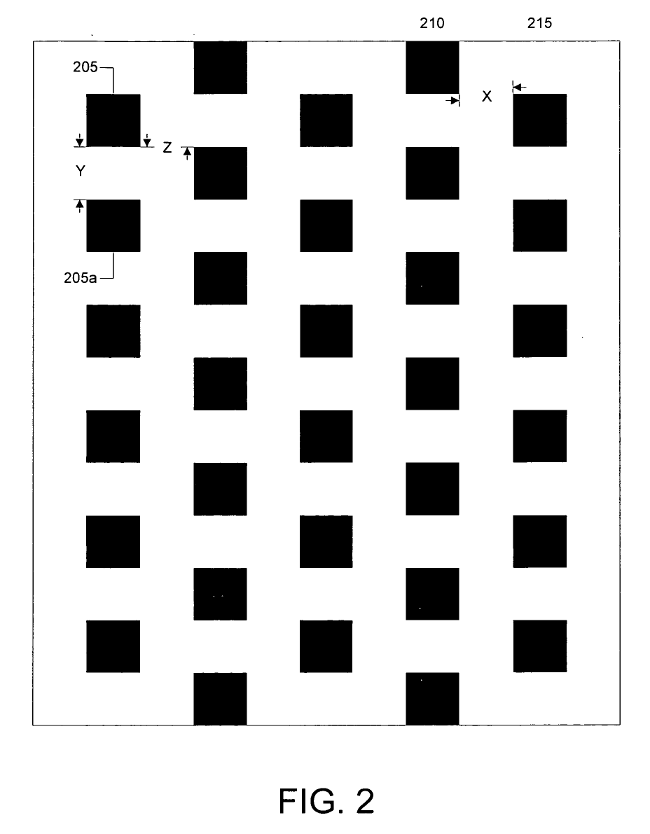

FIG. 2 depicts an exemplary pattern of islanded structures for writeable media that reduces the effects of misalignment between a printer and the writeable media. Each of a plurality of islands may be placed on or in an insulating layer. The islands may be made of a conductive material, such as copper, conductive ink, indium tin oxide, a conductive plastic coating, copper with nickel plating, gold plating or silver plating, or any other conductive material. The insulating layer may be made of any insulating material, such as polyethylene terephthalate. Charge may be placed on an island using one of any number of charge-applying devices, such as a stylus, a bar, a wand, a print head or any other device that can supply charge to an island. In addition, charge may be placed on an island via an electronic circuit in connection with the island. The insulating layer may prevent charge placed on one island from dispersing to adjacent islands. As such, the insulating layer may enable the islands to maintain their charge during and after the printing process.

In an embodiment, each island, such as 205, may be substantially rectangular in shape. In an embodiment, each island may be substantially a square. In such an embodiment, the sides of an island 205 may each be no more than approximately 4 mils. Sides of differing lengths may alternately be used. In an alternate embodiment, each island may be substantially circular and have a diameter of no more than approximately 4 mils. Other shapes, such as, for example, rectangles, trapezoids, ovals and octagons, may also be used without departing from the scope of the invention.

A column of islands, such as 210, may be separated from each adjacent column, one of such columns is 215, by a substantially uniform distance. In FIG. 2, a distance X may represent the distance between column 210 and column 215. The distance X may be equal to the distance between the rightmost edge of islands in column 210 and the leftmost edge of islands in column 215. In an embodiment, the distance X may be no more than approximately 4 mils. A distance Y may separate adjacent islands in the same column, such as 205 and 205a. In an embodiment, the distance Y may be no more than approximately 4 mils. Islands in adjacent columns may be staggered, as shown in FIG. 2. In an embodiment, the distance Z between the top edge of an island and the bottom edge of an island in an adjacent column may be approximately zero.

In an embodiment, islands in a first column are offset by a substantially uniform, non-zero stagger distance with respect to islands in each column that is separated from the first column by an odd number of columns. In other words, in FIG. 2, the column adjacent to the column with islands 205 and 205a, as well as column 210, are offset from the column having islands 205 and 205a by a non-zero stagger distance. In an embodiment, islands in a first column possess substantially the same arrangement as islands in each column that is separated from the first column by an even number of columns (such as column 215 in FIG. 2).

The island widths, separations, shapes and arrangements described above are merely exemplary. Different island widths, separations, shapes and arrangements are also encompassed within the scope of this invention. In addition, differing island widths, separations, shapes and arrangements may be used in a single island structure.

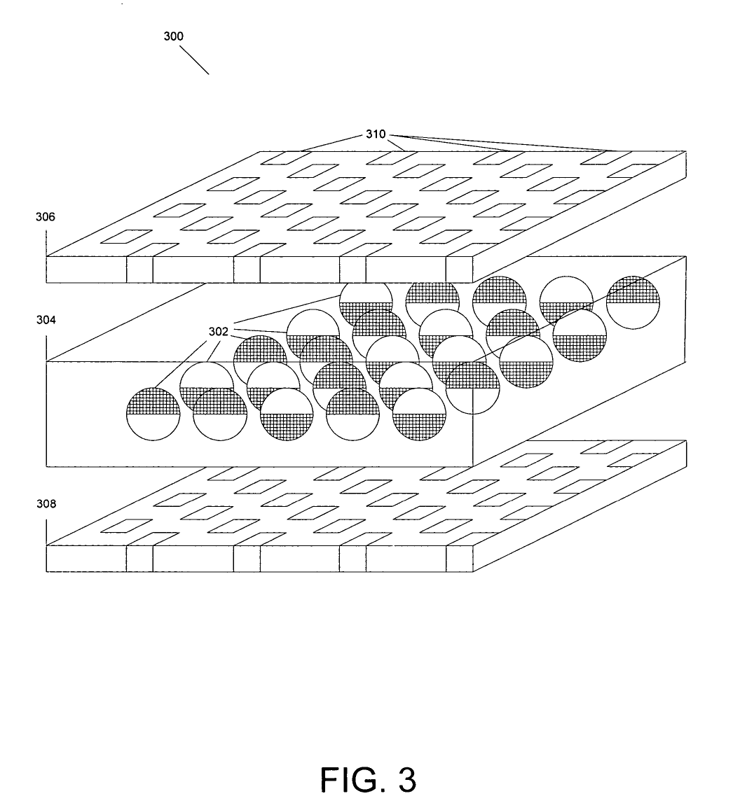

An exemplary display device incorporating the islanded structure is depicted in FIG. 3. The writeable medium 300 may be fabricated by encapsulating a plurality of electro-optic elements 302 in a panel 304 made from an elastomer or other suitable material such that each element 302 is capable of changing its electro-optic condition in response to a selectively applied electric field. The panel 304 may be disposed between two substrates 306 and 308. The islanded structure 310 may be incorporated into the first substrate 306 or may be located on a side of the first substrate 306 opposite the panel 304. Note that the electro-optic elements 302 in FIG. 3 are not shown to scale. Typically, such elements 302 have a diameter that is substantially smaller than the width of the islands of the islanded structure 310. The second substrate 308 may include, for example, a solid backplane of a conductive material. Alternatively, the solid backplane may be placed on a side of the second substrate 308 opposite the panel 304. In an embodiment, other structures may be used instead of the backplane.

In an embodiment, a print head (not shown) may pass over the first substrate to supply charge to the islands of the islanded structure 310. As the print head moves across the writeable medium 300, charge is applied or removed from portions of the print head substantially corresponding to rows of islands of the islanded structure 310. If charge is applied to a portion of the print head over an island, the charge may be transferred to the island. Depending upon the charge of the backplane on the second substrate 308, one or more elements proximate to the island may become or remain a “written” color. Alternatively, the application of charge to an island may cause one or more elements proximate to the island to become or remain an “erased” color. This process may be used to form a line in the writeable medium 300 by keeping a portion of the print head charged as the print head moves across the writeable medium 300.

Changing the orientation of an element produces “written” and “erased” colors. In an embodiment, an element may include a GYRICON® bead. Each element may include, for example, two hemispheres of differing colors, such as black and white. The elements may each have an intrinsic electric dipole so that the orientation of the element conforms to an applied electric field. When a field exists between an island of the islanded surface structure 310 and the backplane of the writeable medium 300, the element rotates in response to the field. Depending upon the polarity of the field, one of the “written” (i.e., black) and the “erased” (i.e., white) hemispheres of an element may be displayed to an observer. If no field exists between the island and the backplane, the element may maintain its orientation. The colors black and white are used only to illustrate contrasting examples; in fact any two colors, which may include two shades of a single color, may be used within the scope of the invention. Note that the use of black and white hemispheres is merely illustrative and that other colors or elements, such as those described above, may be used.

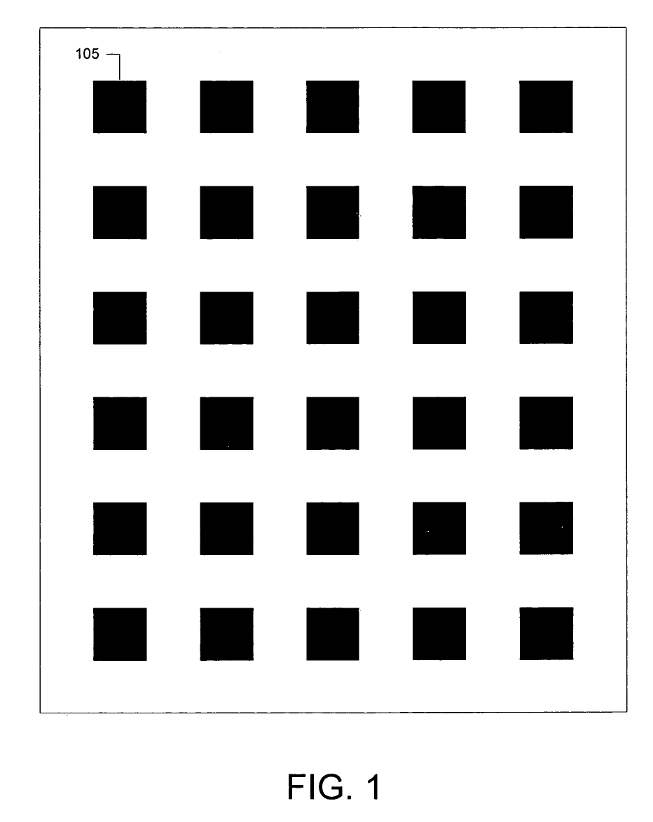

The islanded structure 310 may substantially or completely eliminate the possibility of misalignment between the printer and the writeable medium 300 because of the staggered nature of the islands if printing is performed, for example, horizontally (with respect to the orientation of FIG. 2). As a print head moves across the writeable medium 300, a horizontal line may be displayed substantially as intended. In other words, no jogging of the line may occur during the printing process. This may occur because the distance Z between adjacent islands is substantially zero. In other words, a line that would fall between two rows of islands in FIG. 1 is properly displayed due to the offset columns of the islanded structure shown in FIG. 2. In an alternate embodiment, the arrangement of the islands may be such that vertical lines may be drawn with no jogging by, for example, rotating the layout of the islanded structure 310 by ninety degrees.

Although the invention has been described with reference to the preferred embodiments, it will be apparent to one skilled in the art that variations and modifications are contemplated within the spirit and scope of the invention. The drawings and description of the disclosed embodiments are made by way of example rather than to limit the scope of the invention, and it is intended to cover within the spirit and scope of the invention all such changes and modifications.

1. A writeable medium, comprising:
a panel comprising a plurality of electro-optic elements;
a layer comprising an insulating material; and
a plurality of islands located on one side of the layer, wherein each island comprises a conductive material, wherein the plurality of islands are arranged in a plurality of columns, wherein islands in a first column are offset by a substantially uniform, non-zero stagger distance with respect to islands in each second column that is separated from the first column by an odd number of columns, wherein islands in the first column possess substantially the same arrangement as islands in each third column that is separated from the first column by an even number of columns.

2. The writeable medium of claim 1 wherein a distance between adjacent islands in a column is approximately equal to the stagger distance.

3. The writeable medium of claim 1 wherein a distance between adjacent islands in a column is no more than approximately 4 mils.

4. The writeable medium of claim 1 wherein the stagger distance is no more than approximately 4 mils.

5. The writeable medium of claim 1 wherein a distance between adjacent columns is no more than approximately 4 mils.

6. The writeable medium of claim 1 wherein an island is substantially a square.

7. The writeable medium of claim 6 wherein each side of the island is no more than approximately 4 mils in length.

8. The writeable medium of claim 1 wherein an island is substantially circular.

9. The writeable medium of claim 8 wherein the diameter of the island is no more than approximately 4 mils.

10. The writeable medium of claim 1 wherein an island is substantially rectangular.

11. The writeable medium of claim 1 wherein an island is substantially trapezoidal.

12. The writeable medium of claim 1 wherein an island is substantially ovular.

13. The writeable medium of claim 1 wherein an island is substantially octagonal.

14. A writeable medium, comprising:
a panel comprising a plurality of electrically changeable elements; and
a layer comprising an insulating material and a plurality of islands, wherein each island comprises a conductive material, wherein the plurality of islands are arranged in a plurality of columns, wherein islands in a first column are offset by a substantially uniform, non-zero stagger distance with respect to islands in each second column that is separated from the first column by an odd number of columns, wherein islands in the first column possess substantially the same arrangement as islands in each third column that is separated from the first column by an even number of columns.

15. The writeable medium of claim 14 wherein a distance between adjacent islands in a column is approximately equal to the stagger distance.

16. The writeable medium of claim 14 wherein a distance between adjacent islands in a column is no more than approximately 4 mils.

17. The writeable medium of claim 14 wherein the stagger distance is no more than approximately 4 mils.

18. The writeable medium of claim 14 wherein a distance between adjacent columns is no more than approximately 4 mils.

19. The writeable medium of claim 14 wherein an island is substantially a square.

20. The writeable medium of claim 19 wherein each side of the island is no more than approximately 4 mils in length.

21. The writeable medium of claim 14 wherein an island is substantially circular.

22. The writeable medium of claim 21 wherein the diameter of the island is no more than approximately 4 mils.

23. The writeable medium of claim 14 wherein an island is substantially rectangular.

24. The writeable medium of claim 14 wherein an island is substantially trapezoidal.

25. The writeable medium of claim 14 wherein an island is substantially ovular.

26. The writeable medium of claim 14 wherein an island is substantially octagonal.

27. A display device, comprising:
a print head; and
a writeable medium comprising a panel comprising a plurality of electrically changeable elements, a layer comprising an insulating material, and a plurality of islands located on one side of the layer,
wherein each island comprises a conductive material, wherein the plurality of islands are arranged in a plurality of columns, wherein islands in a first column are offset by a substantially uniform, non-zero stagger distance with respect to islands in each second column that is separated from the first column by an odd number of columns, wherein islands in the first column possess substantially the same arrangement as islands in each third column that is separated from the first column by an even number of columns.

28. A display device, comprising:
a print head; and
a writeable medium comprising a panel comprising a plurality of electrically changeable elements, and a layer comprising an insulating material and a plurality of islands,
wherein each island comprises a conductive material, wherein the plurality of islands are arranged in a plurality of columns, wherein islands in a first column are offset by a substantially uniform, non-zero stagger distance with respect to islands in each second column that is separated from the first column by an odd number of columns, wherein islands in the first column possess substantially the same arrangement as islands in each third column that is separated from the first column by an even number of columns.
